(19) United States
(12) Patent Application Publication
(10) Pub. No.: US 2023/0231520 A1
(43) Pub. Date: Jul. 20, 2023

(54) A SPIN HALL ISING MACHINE AND METHOD FOR OPERATING SUCH

(71) Applicant: NanOsc AB, Kista (SE)

(72) Inventors: Mohammad ZAHEDINEJAD, Askim (SE); Shreyas MURALIDHAR, Eindhoven (SE); Johan AKERMAN, Sollentuna (SE); Afshin HOUSHANG, Eindhoven (SE); Ahmad AWAD, Västra Frölunda (SE)

(21) Appl. No.: 18/007,887

(22) PCT Filed: Jun. 2, 2021
(86) PCT No.: PCT/SE2021/050515

§ 371 Date: Dec. 2, 2022

(30) Foreign Application Priority Data
Jun. 3, 2020 (SE) 2050641-6

(51) Int. Cl. H03B 15/00; H10N 10/00; G06N 5/01

(52) U.S. Cl. CPC H03B 15/006; H10N 10/00; G06N 5/01

(57) ABSTRACT

The present invention relates to an Ising Machine utilizing a network of spin Hall nano-oscillators (SHNOs) suitable or computational tasks such as optimization problems. The spin Hall nano-oscillator based Ising machine is provided with a tuning nitarranged to effect the characteristics of at least one individual spin Hall nano-oscillators of the array; and a SHNO read-out unit arranged to detect and transfer a state of at least a one individual spin Hall nano-oscillators of the array.

### TECHNICAL FIELD

The present invention relates to an Ising Machine utilizing a network of spin Hall nano-oscillators (SHNOs) suitable for computational tasks such as optimization problems. The invention further relates to a method of operating such network.

### BACKGROUND

Conventional computers based on Von-Neumann architecture are unable to efficiently address a certain class of problems known as Combinatorial Optimization (CO) problems. These are by no means rare and manifest themselves in some critically important areas such as business operations, manufacturing and research, IC circuit design, protein folding and DNA sequencing, discovery of new medicines, and efficient big-data clustering, to name a few. In parallel, Moore's law continues to slow down and approach its limits making it even more vital to rethink current computation schemes and explore alternative paradigms. One important avenue in that regard is the concept of natural computing (NC) where a specific problem is mapped onto the physics of a system and lets the system converge to a stable ground state, which is the solution to the given problem. Within the realm of NC many proposal has been put forward among which quantum computers (QCs), Ising Machines, and even combinations of both, are currently the most studied examples.

An Ising Machine (IM) is any hardware, whose node interactions can be described by an Ising Hamiltonian, and is tasked with finding its ground state, which represent the solution to a specific CO problem defined by the connection strengths between nodes. Guided by the individual interactions between all nodes, all evaluated continuously through the inherent parallelism of the system, the IM wanders through its multivariate energy landscape, typically helped by different types of annealing schemes to avoid local minima, and find its global minimum in a factorially faster time than a serial computation would. Given the importance of CO problems and the factorial efficiency of IMs in solving these kind of problems, there have been multiple recent hardware implementations such as quantum annealers, CMOS annealers, nano-magnet network arrays, electronic oscillators and laser networks.

Despite impressive efforts, all demonstrated IM implementations face serious shortcomings, typically operating at millikelvin temperature, requiring large cryogenic facilities with kWs of power consumption. The technology has also not scaled well to larger IMs, comes with a very high production cost, and suffers from a relatively sparse qubit connectivity.

Coherent Ising Machines (CIM) implemented using externally pumped optical parametric oscillators (OPO) are room-temperature alternatives. However, they too face serious challenges in terms of scaling, foot-print, and high power consumption. In addition, CIMs require optical table infrastructure and kilometer-long optical fibers in order to accommodate all time-multiplexed optical parametric oscillators. Once, these systems are built and the operating frequency is set, no further tuning is available unless new hardware with a new architecture replaces the existing one.

As a room-temperature digital CMOS alternative, the company Fujitsu, in 2018, announced its state-of- the-art field-programmable digital array (FPGA) digital annealer unit (DAU), offering 8192 simulated qubits with all-to-all connectivity allowing all qubits to exchange signals freely. Thanks to their superior connectivity, DAUs are capable of dealing with sizeable real-world scale CO problems. However, they are still relying on the Von-Neumann computing paradigm with the added reconfigurability of FPGAs and not the nature of a physical system. It is hence not likely that this approach will be able to scale to much larger systems.

Wang, T. and Roychowdhury, J. [2019, June. OIM: Oscillator-based Ising Machines for Solving Combinatorial Optimisation Problems. In International Conference on Unconventional Computation and Natural Computation (pp. 232-256). Springer, Cham.] discloses non-linear oscillator-based IMs based on off-the-shelf electronics. As demonstrated, the phase dynamics of a network of coupled oscillators can minimize a scalar function called a Lyapunov function, which serves as a measure of the network stability. Once the networks is under second-harmonic injection locking (SHIL), the individual phase of any oscillators in the network can only obtain binarized values, i.e., 0 or π. Under SHIL, the Lyapunov function directly translates into the Ising Hamiltonian, and the network can operate as an IM. Annealing can be implemented in different ways, e.g. through varying the strength of the injected signal. The authors demonstrated a PCB prototype using a network of 240 resistively coupled CMOS LC oscillators with a maximum of 1200 connections, achieving a remarkable solution time of 1 ms for a moderate operating frequency of 1 MHz and a very modest power consumption of only 5 W. In a similar demonstration a network of four all-to-all LC coupled oscillators was shown to solve Max-Cut problems of small size 7. Both reports forecast a significant boost in processing speed and solutions quality if the CMOS coupled oscillators could be realized in large numbers and operating at GHz frequencies.

### SUMMARY OF THE INVENTION

The object of the invention is to provide an Ising machine for computational purposes and method of operation that overcomes the drawbacks of prior art Ising machines.

This is achieved by the device as defined in claim 1, the method defined in claim 19, and the use defined in claim 12.

According to one aspect of the invention a spin Hall nano-oscillator based Ising machine comprising at least one array of spin Hall nano-oscillators, each spin Hall nano-oscillators comprising a nano-constricted region is provided. The spin Hall nano-oscillator based Ising machine is provided with:
a tuning unit arranged to effect the characteristics of at least one individual spin Hall nano-oscillators of the array; and
a SHNO read-out unit arranged to detect and transfer a state of at least a one individual spin Hall nano-oscillators of the array.

According to embodiments of the invention at least a portion of the spin Hall nano-oscillators are provided with an individual SHNO-based units arranged on or in close proximity to the individual SHNOs. The SHNO-based units may comprise means for electrically influencing the nano-constriction region of the SHNO. The SHNO-based units may comprise a conductor that is arranged over the nano-constricted region of each SHNO and arranged to control a voltage over the SHNO. The SHNO-based units may comprise a memristor gate arranged on top of the nano-constriction of the SHNOs.

According to embodiments of the invention at least a portion of the spin Hall nano-oscillators are provided with an individual SHNO read-out unit arranged on, or in close proximity to, the individual SHNO, wherein the SHNO read-out unit is arranged to detect and transfer information of a state of the associated individual SHNO. The SHNO read-out unit may comprise a magnetic tunnel junction or an optical detector.

According to one aspect of the invention a method of operating a spin Hall nano-oscillator based Ising machine as above described is provided. The method comprises the steps of:
a) defining a problem suitable for computing with the IM machine, typically a CO problem;
b) mapping the CO problem as variables defined by the phase state of the SHNOs 11 and their coupling strength by the SHNO tuning unit or SHNO tuning units within the array;
c) annealing the SHNO based Ising machine;
d) engaging the SHNO read-out unit 14 or SHNO read-out units to read out the states of the SHNOs; and
e) calculate the Ising Hamiltonian using read out states as one of the possible solutions for the CO problem aiming to minimize the Ising Hamiltonian.

The steps steps c) to e) may be repeated for a limited number of iterations to have a statistical information of solutions occurrence. The number of repetitions may be predetermined or determined dynamically during operation.

According to embodiments of the method the annealing step is performed by one, or a combination of: i) altering the global drive current, ii) altering the global external applied field magnitude and/or angle, iii) altering the strength of the injected second harmonic of the intrinsic frequency of the array.

According to one aspect of the invention the use of an array of spin Hall nano-oscillators in a computational Ising machine is provided. The use may include the of an array of spin Hall nano-oscillators, a tuning unit arranged to effect the characteristics of at least one individual spin Hall nano-oscillators of the array, and a SHNO read-out unit; arranged to detect and transfer a state of at least a one individual spin Hall nano-oscillators of the array, in an computational Ising machine.

### BRIEF DESCRIPTION OF THE DRAWINGS

The features and advantages of the present invention will become further apparent from the following detailed description and the accompanying drawing, of which:

FIG. 1a-b: a) illustrates schematically in a top view a SHNO based Ising machine 10 according to one embodiment of the invention, and b) in a side view a SHNO based Ising machine 10 according to one embodiment;

FIG. 2 illustrates schematically a SHNO based Ising machine 10 according to one embodiment of the invention;

FIG. 3 SHNO arrays: A scanning electron microscopy of a 2×2 SHNO array is shown together with a schematic for a 1×2 array. SHNOs are made of a Pt/NiFe bilayer, each 5 nm thick. Width of each individual SHNO is W=120 nm and the pitch size is P=300 nm. H_{IP} shows the in-plane direction of the external magnetic field, H.

FIG. 4: Second harmonic injection locking (SHIL) of SHNO arrays: PSD of a 1×2 SHNO array (a) as a function of injection power, PH, at a fixed injected frequency ƒ_{IL}=18.69 GHz, and (b) as a function of injection frequency at a fixed P_{IL}=0 dB. In (a) the array starts off at a syncronized state (Synced state) while in (b) SHNOs are not synchronized. In both cases, after the array is locked to the external source, the linewidth decreases, and the power shows intermittent fluctuations between a high and low energy state. The same trend is observed in 2×2 arrays. However, in the 2×2 arrays, three different energy levels can be distinguished once the array is locked to the external source as shown in (c) and (d).

FIG. 5: (A) SEM image of 2×2 SHNO array operating at ƒ₀˜7.8 GHz which was fine-tuned by applied field (II) while under SHIL at P_{IL}=0 dBm and ƒ_{IL}=15.6 GHz. The BLS scan direction is shown by a green dashed arrow. (B)-(E) show the SHNOs SW intensities for the BLS light sensitive only to Φ=90 and 270° phase values with respect to the injected signal. SHNOs in (B) and ((C)) are energized with 180° phase difference (<↑↓>) when 2ƒ₀<ƒ_{IL} and in (D) and (E) with 0° phase difference (<↑↑>) when 2ƒ₀˜ƒ_{IL}. (F) SEM image of a 2×2 SHNO array with corresponding BLS line scan directions. The array operates at ƒ₀=X GHz and ƒ_{IL} was fixed at X GHz. phase-resolved (PR-BLS) line scans are shown in (G)-(J) for P_{IL}=X dBm corresponding to <↓↑↑↓> phase state while (K)-(N) shows <↓↓↓↓> state obtained at P_{IL}=Y dBm. (O)-(R) BLS counts for the least stable phase state <↓↓↑↓> at P_{IL}=Z dBm measured by sweeping the BLS light phase Φ.

### DETAILED DESCRIPTION OF THE INVENTION

Terms such as “top”, “on top”, “bottom”, upper“, lower”, “below”, “above” etc, are used merely with reference to the geometry of the embodiment of the invention shown in the drawings and/or during normal operation of the described system and its components and are not intended to limit the invention in any manner.

One of the most intriguing properties of spin Hall nand-oscillators(SHNOs) is their ability to mutually synchronize in both one and two dimensions, clearly demonstrating strong inter-oscillator coupling. Other related synchronized nano-oscillators, such as spin torque nano-oscillators (STNOs) were recently used for vowel recognition at about 300 MHz However, scaling up to much larger STNO arrays have proven difficult due to the slow progress in number of mutually synchronized STNOs.

The inventors of the present invention have realized that SHNOs may be utilized in large-scale oscillator based Ising Machines. The SHNOs have been demonstrated down to lateral dimensions of only 20 nm, operated up to 26 GHz, showing mutual synchronization in two-dimensional arrays of up to 64 oscillators.

A SHNO comprises a multilayer structure with a nano-constriction, in operation, a charge current I_{dc} is injected in the SHNO, gets concentrated in the nano-constriction and drives a spin current Iₛ into a magnetic layer of the multilayer structure. The SHNO generates an output signal V_{rf} through a magneto resistive effect such as anisotropic magnetoresistance, giant magnetoresistance, or tunneling magnetoresistance, or a combination thereof. In spin Hall nano-oscillators (SHNOs), pure spin currents drive local regions of magnetic films and nanostructures into auto-oscillating precession. If such regions are placed in close proximity to each other they can interact and may mutually synchronize. The auto-oscillating may be influenced by for example an externally applied field (Hₑₓₜ), heating and an applied electric field over the nano-constricted region.

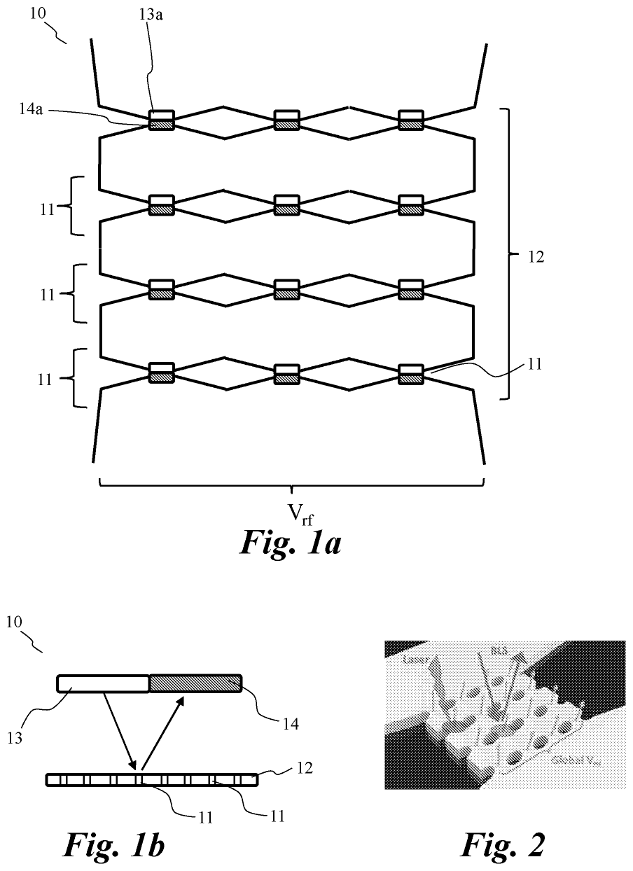

A SHNO based Ising machine 10 according to the invention is schematically illustrated in figure 1a. At least one array 12 of linked SHNOs 11 is provided, here depicted as a plurality of nano-constricted regions. “Linked” should here be understood that adjacent individual SHNOs 11 are sufficiently close to facilitate that a first SHNOs 11a may during operation influence an adjacent second SHNOs 11b. Typically and preferably all SHNOs 11 in the network share the same multilayered structure, so that at least a major portion of the layers in the multilayered structure are continuous in the array 12. The array 12 comprises means for injecting a drive current, typically the same, to all individual SHNOs 11, as well as means for detecting a global output signal, a microwave voltage, V_{rf} and means for applying an externally field, Hₑₓₜ. Such means and methods for applying/detecting are known in the art.

The array 12 may be an ordered two dimensional array as depicted, but also a more complex network for example but not limited to triangular, hexagonal, tailored and random configuration. Also a structure with stacked arrays forming a 3D structure may be envisaged, however requiring a complex structur for input/read-out, applying fields etc.

The SHNO based Ising machine 10 according to the invention comprises a SHNO tuning unit 13 or a plurality of SHNO tuning units 13, that is configured to act on at least a portion of the individual SHNOs 11 of the array 12. The SHNO tuning unit 13 has the ability to alter, for example and preferably, the auto-oscillating frequency of an individual SHNO 11 and thereby effect the coupling to adjacent SHNOs. The SHNO tuning unit may implemented as a plurality of SHNO-based units 13b typically arranged on or in close proximity to the individual SHNOs 11, which is illustrated in FIG. 1a. Such SHNO-based units 13b may comprise means for electrically influencing the nano-constriction region of the SHNO 11, for example a voltage gate.

Alternatively, the SHNO tuning unit 13 is arranged a distance from the array 12 and comprises means to effect the SHNOs 11 from that distance, for example with laser heating, and in particular with the use of spatial light modulation, which is schematically illustrated in FIG. 1b.

The SHNO based Ising machine 10 according to the invention comprises a SHNO read-out unit 14 or a plurality of SHNO read-out units 14a, that is configured to interact with at least a portion of the individual SHNOs 11 of the array 12. The SHNO read-out unit/units 14/14b detects and transfers information of a state of an individual SHNO 11, for example the phases of the precessing magnetization in the nano-constriction of the individual SHNO 11. The SHNO read-out unit 14 may comprises a plurality of SHNO read-out units 14b typically arranged on or in close proximity to the individual SHNOs 11, which is illustrated in figure 1a. The SHNO read-out units 14b may optical or electrical detection to detect the state of the individual SHNO 11.

Also the SHNO read-out unit 14 may be arranged a distances from the array 12 if the read-out is optical and may be directed to all, or at least a portion, of the SHNOs 11 of the array 12, which is schematically illustrated in FIG. 1b.

According to one embodiment of the invention the SHNO tuning units 13b comprises a conductor that is arranged over the nano-constricted region of each SHNO 11 and arranged to control a voltage over the SHNO 11.

According to one embodiment of the invention the SHNO tuning units 13b comprises a memristor gate arranged on top of each nano-constriction of the SHNOs 11.

According to one embodiment of the invention the SHNO tuning units 13b comprises a memristor gate arranged on top of each nano-constriction of the SHNOs 11. The memristor gates may provide embedded memories and thereby act as in-processor memory elements for the SHNO based Ising machine 10.

According to one embodiment of the invention the SHNO read-out units 14b comprises a magnetic tunnel junction which can be accessed individually by multiplexing readout technique.

According to one embodiment of the invention both the SHNO tuning unit 13 and the SHNO read-out unit 14 are optical units arranged to act on a plurality of SHNOs 11, which is schematically illustrated in FIG. 2. The SHNO tuning unit 13 may comprise a laser that can be control to heat the individual nano-constriction regions of the SHNOs 11. Spatial light modulation may be used to control the heating. The SHNO read-out unit 14 may comprise means for phase-resolved Brillouin Light Scattering (phase-BLS) microscopy to directly observe the individual phases of the precessing magnetization in the nano-constriction regions of each SHNO.

According to one aspect of the invention a method of operating a SHNO based Ising machine 10 according to the invention is provided. The method of operation comprises the main steps of:
a) Defining a problem suitable for computing with the IM machine, typically a CO problem
b) Mapping the CO problem as variables defined by the phase state of the SHNOs 11 and their coupling strength by the SHNO tuning unit 13/SHNO tuning units 13b within the array 12.
c) Anneal the SHNO based Ising machine 10. Annealing should effect the global coupling of the entire array and may be performed by for example: i) via the global drive current, ii) via the global external applied field magnitude and/or angle, iii) via the strength of the injected second harmonic of the intrinsic frequency of the array.
d) Engaging the SHNO read-out unit 14/SHNO read-out units 14b to read out the states of the SHNOs 11.
e) Calculate the Ising Hamiltonian using read out states as one of the possible solutions for the CO problem aiming to minimize the Ising Hamiltonian.
f) Repeat the steps c-e for a limited number of iterations to have a statistical information of solutions occurrence.

### Example

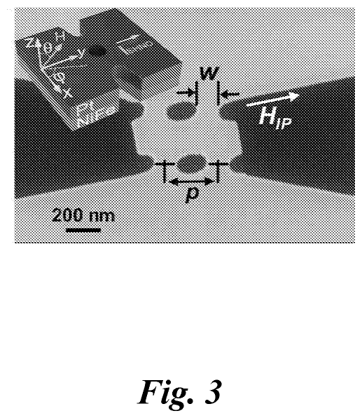

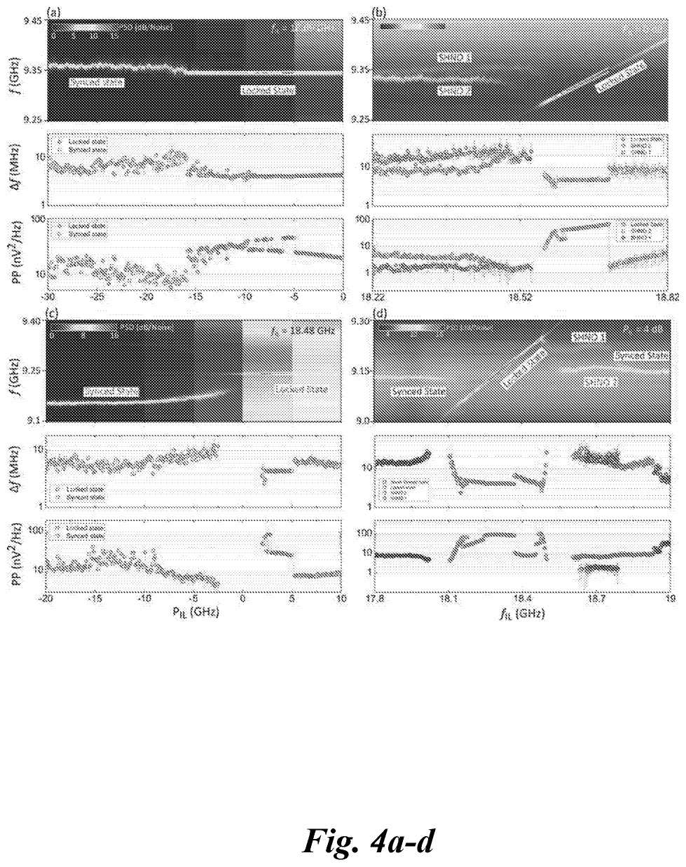

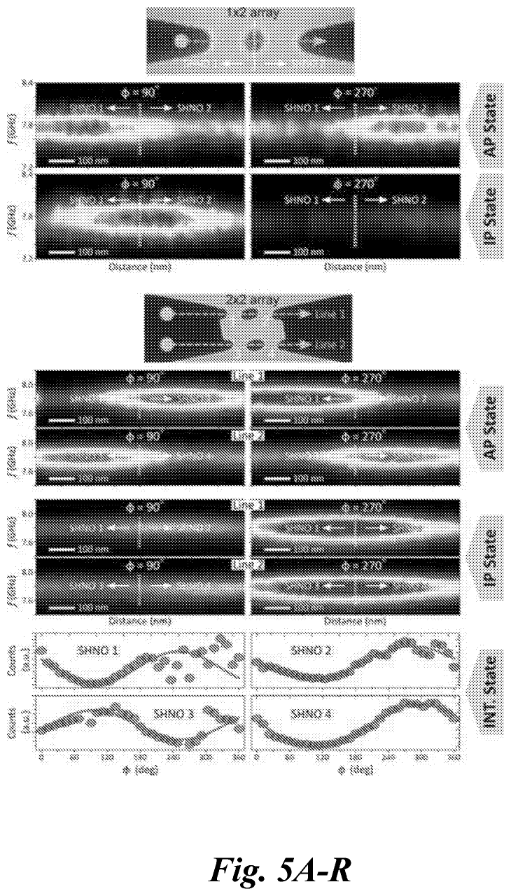

SHNO based Ising machines 10 according to the invention was fabricated and tested. We demonstrate robust phase binarization of both 1×2 and 2×2 SHNO arrays using second-harmonic microwave current injection locking. The phase binarization manifests itself as distinct microwave output power levels, which are readily distinguished using electrical means. In addition, we use phase-resolved Brillouin Light Scattering (phase-BLS) microscopy to directly observe the individual phases of the precessing magnetization in each nano-constriction. The different high/low microwave output states can be directly mapped onto different in- and anti-phase states in both types of array, and, as expected, an additional intermediate power mixed-phase state in the 2×2 array. The different states can be accessed using either different injected power levels or a detuned frequency of the injected signal. We also find that the use of different intensity of the phase-BLS laser can affect the phase state of the array. We ascribe this to laser heating modifying the individual nano-constriction and/or the coupling strength between nano-constrictions. It should hence be possible to use spatial light modulation to heat different parts of the SHNO array in different amounts and map an arbitrary CO problem onto an otherwise generic and homogeneous SHNO array. Our device as mentioned before is a two dimensional array of nano-constrictions each with width of W=120 nm and a pitch size of P=200 nm for the 1×2 array and P=300 nm for the 2×2 one. A schematic illustration of a 1×2 array is show in in FIG. 3 with H being the external magnetic field, θ is the out-of-plane angle, φ is the in-plane angle of H, and I_{SHNO} shows the direction of the charge current. The scanning electron microscopy of a 2×2 array is also show in FIG. 3 in which H_{IP} shows the in-plane direction of the applied magnetic field. Devices under study are made of a bilayer of Pt (5 nm)/NiFe (3 nm), θ and φ are fixed to 78 and 24 degrees, respectively. For the case of 1×2 array, a current of I_{SHNO}=3 mA and H=6400 Oe was applied. A single mode corresponding to two synchronized nano-constrictions was detected at about 9.35 GHz. Using an external signal generator and as shown in S.1 of supplementary, an external microwave signal, ƒ_{IL}=18.

The foregoing detailed description is intended to illustrate and provide easier understanding of the invention, and should not be construed as limitations. Alternative embodiments will become apparent to those skilled in the art without departing from the spirit and scope of the present invention.

1. A spin Hall nano-oscillator based Ising machine comprising
at least one array of spin Hall nano-oscillators, each spin Hall nano-oscillators comprising a nano-constricted region, a tuning unit arranged to effect the characteristics of at least one individual spin Hall nano-oscillators of the array; and
a SHNO read-out unit arranged to detect and transfer a state of at least a one individual spin Hall nano-oscillators of the array.

2. The spin Hall nano-oscillator based Ising machine according to claim 1, wherein at least a portion of the spin Hall nano-oscillators are provided with an individual SHNO-based units arranged on or in close proximity to the individual SHNOs.

3. The spin Hall nano-oscillator based Ising machine according to claim 2, wherein the SHNO-based units comprise means for electrically influencing the nano-constriction region of the SHNO.

4. The spin Hall nano-oscillator based Ising machine according to claim 3, wherein the SHNO-based units comprise a conductor that is arranged over the nano-constricted region of each SHNO and arranged to control a voltage over the SHNO.

5. The spin Hall nano-oscillator based Ising machine according to claim 3, wherein the SHNO-based units comprise memristor gate arranged on top of the nano-constriction of the SHNOs.

6. The spin Hall nano-oscillator based Ising machine according to claim 1, wherein at least a portion of the spin Hall nano-oscillators are provided with an individual SHNO read-out unit arranged on, or in close proximity to, the individual SHNO, wherein the SHNO read-out unit is arranged to detect and transfer information of a state of the associated individual SHNO.

7. The spin Hall nano-oscillator based Ising machine according to claim 3, wherein the SHNO read-out unit comprises a magnetic tunnel junction.

8. The spin Hall nano-oscillator based Ising machine according to claim 3, wherein the SHNO read-out unit comprises an optical detector.

9. A method of operating a spin Hall nano-oscillator based Ising machine according to claim 1, the method comprising the steps of:
a) defining a problem suitable for computing with the IM machine, typically a CO problem;
b) mapping the CO problem as variables defined by the phase state of the SHNOs and their coupling strength by the SHNO tuning unit or SHNO tuning units within the array;
c) annealing the SHNO based Ising machine;
d) engaging the SHNO read-out unit or SHNO read-out units to read out the states of the SHNOs; and
e) calculate the Ising Hamiltonian using read out states as one of the possible solutions for the CO problem aiming to minimize the Ising Hamiltonian.

10. The method of operating a spin Hall nano-oscillator based Ising machine according to claim 9, further comprising repeating steps c) to e) for a limited number of iterations to have a statistical information of solutions occurrence.

11. The method of operating a spin Hall nano-oscillator based Ising machine according to claim 9, wherein the annealing step is performed by one, or a combination of: i) altering the global drive current, ii) altering the global external applied field magnitude and/or angle, and iii) altering the strength of the injected second harmonic of the intrinsic frequency of the array.

12. Use of an array of spin Hall nano-oscillators in a computational Ising machine.

13. A method comprising the use of an array of spin Hall nano-oscillators, a tuning unit arranged to effect the characteristics of at least one individual spin Hall nano-oscillators of the array, and a SHNO read-out unit arranged to detect and transfer a state of at least a one individual spin Hall nano-oscillators of the array, in an computational Ising machine.
